(19) United States
(12) Patent Application Publication
(10) Pub. No.: US 2025/0338373 A1
(43) Pub. Date: Oct. 30, 2025

(54) IDEAL DIODE BYPASS CIRCUIT CONTROL SYSTEM

(71) Applicant: TEXAS INSTRUMENTS INCORPORATED, DALLAS, TX (US)

(72) Inventors: YANG WU, WUHAN (CN); ABHIJEET GOPAL GODBOLE, BANGALORE (IN); DILIP KUMAR JAIN, BANGALORE (IN)

(21) Appl. No.: 18/787,354

(22) Filed: Jul. 29, 2024

Related U.S. Application Data
(60) Provisional application No. 63/638,454, filed on Apr. 25, 2024.

(51) Int. Cl. H05B 45/3725; H01L 31/02; H01L 31/05; H05B 45/34

(52) U.S. Cl. CPC H05B 45/3725; H05B 45/34; H10F 19/90; H10F 77/955

(57) ABSTRACT

One example circuit includes an ideal diode controller including a voltage clamp circuit, an anode terminal, a cathode terminal, and a control terminal arranged between the anode and the cathode. The circuit also includes a bypass switch controlled by a switch signal provided from the control terminal. The bypass switch can operate in a closed state in a first mode in which a first voltage at the anode terminal is greater than or approximately equal to a second voltage at the cathode terminal to conduct a bypass current. The bypass switch can operate in an open state in a second mode in which the first voltage is less than the second voltage. The voltage clamp circuit can be configured to clamp an amplitude of the second voltage to a predefined threshold amplitude relative to an amplitude of the first voltage in the second mode.

### RELATED APPLICATIONS

This application claims priority from U.S. Patent Application Ser. No. 63/638,454, filed 24 Apr. 2024, which is incorporated herein in its entirety.

### TECHNICAL FIELD

This description relates to electronic circuits, and more specifically to an ideal diode bypass circuit control system.

### BACKGROUND

Renewable and natural energy sources are becoming more popular for generating power. Such renewable and natural energy sources are persistently available, require no fuel, generate no pollutants, and are more widely accepted in a more ecologically conscientious society. Such renewable and natural energy sources can be scaled to a great extent to provide renewable power plants. One such renewable power plant is a solar field (i.e., solar farm) that harnesses a large amount of solar energy to generate electricity for a public power grid to provide clean and renewable energy to a community. A solar field can be implemented as a large-scale photovoltaic system that includes a large number of photovoltaic modules (i.e., solar panels) arranged in series to convert light directly to electricity.

Because the photovoltaic modules of a solar field are arranged in series, failure of one of the photovoltaic modules can result in power loss of the entire system. To avoid shutdown of an entire photovoltaic system in response to failure of one photovoltaic module, a photovoltaic system can include bypass circuits that are arranged in parallel with each photovoltaic module. Therefore, in response to failure of one of the photovoltaic modules, the bypass circuit can provide a bypass current path to maintain the series current through the series-connected photovoltaic system. As an example, the bypass circuit can be or can operate as a diode to facilitate current flow in only one direction. However, a high voltage generated by the respective photovoltaic module provided across the bypass circuit can result in breakdown or failure of the bypass circuit.

### SUMMARY

One example circuit includes an ideal diode controller including a voltage clamp circuit, an anode terminal, a cathode terminal, and a control terminal arranged between the anode and the cathode. The circuit also includes a bypass switch controlled by a switch signal provided from the control terminal. The bypass switch can operate in a closed state in a first mode in which a first voltage at the anode terminal is greater than or approximately equal to a second voltage at the cathode terminal to conduct a bypass current. The bypass switch can operate in an open state in a second mode in which the first voltage is less than the second voltage. The voltage clamp circuit can be configured to clamp an amplitude of the second voltage to a predefined threshold amplitude relative to an amplitude of the first voltage in the second mode.

Another example includes a solar power system. The system includes a plurality of solar panel power systems arranged in series and an inverter electrically coupled to the solar panel power systems. The system also includes a plurality of bypass circuits that are each arranged in parallel with a respective one of the solar panel power systems. Each of the bypass circuits being configured to conduct a bypass current via a bypass switch in a first mode of the bypass circuits corresponding to a first condition of the respective one of the solar panel power systems, and to clamp a voltage across the bypass circuit to a predefined threshold amplitude in a second mode of the bypass circuits corresponding to a second condition of the respective one of the solar panel power systems.

Another example includes a circuit. The circuit includes a charge pump having a first input, a second input, and an output. The circuit also includes a control driver having a first input, a second input, and an output. The first input of the control driver can be coupled to the first input of the charge pump, and the second input of the control driver can be coupled to the second input of the charge pump. The circuit also includes a voltage clamp circuit having a control terminal, a first terminal, and a second terminal. The control input can be coupled to the second inputs of each of the charge pump and the control driver. The first terminal can be coupled to the first input of each of the charge pump and the control driver. The circuit also includes a first bypass terminal coupled to the second input of each of the charge pump and the control driver, a second bypass terminal coupled to the second terminal of the voltage clamp circuit, and a control bypass terminal coupled to the output of the control driver.

### BRIEF DESCRIPTION OF THE DRAWINGS

FIG. 1 is an example diagram of a solar power system.

FIG. 2 is an example diagram of the solar power system of FIG. 1.

FIG. 3 is an example of a bypass circuit.

FIG. 4 is an example diagram of operation of the bypass circuit of FIG. 3.

FIG. 5 is another example diagram of operation of the bypass circuit of FIG. 3.

FIG. 6 is another example diagram of operation of the bypass circuit of FIG. 3.

### DETAILED DESCRIPTION

This description relates to electronic circuits, and more specifically to an ideal diode bypass circuit control system. A bypass circuit can be arranged in parallel with a voltage source, such as one or more solar panels, to provide an alternate current path for a current through the voltage source. As an example, in a solar power system, a plurality of solar panel power systems can be arranged in series with each other and can be electrically coupled to an inverter. As described herein, the term “solar panel power system” refers to a set of one or more photovoltaic modules (hereinafter “solar panels”) and parallel-coupled solar equipment that generates a voltage in response to sunlight. The solar power system can include a bypass circuit arranged in parallel with each of the solar panel power systems to provide an alternate current path for the current associated with the solar power in response to a deactivation of or a failure condition of the respective solar panel power system.

The bypass circuit can include an ideal diode controller and a bypass switch. As an example, the ideal diode controller and the bypass switch can cooperate to emulate the behavior of a diode with respect to voltage across the bypass circuit. For example, the ideal diode controller can include an anode terminal, a cathode terminal, and a control terminal that is configured to control the bypass switch. For example, during a first mode corresponding to a normal operating condition of the respective solar panel power system, the bypass circuit can exhibit a higher voltage on the cathode terminal than the anode terminal. Therefore, no current is provided through the bypass circuit, thereby allowing the solar panel power system to provide a portion of the current through the inverter. However, during a second mode corresponding to a deactivated or failure condition of the respective solar panel power system, the bypass circuit can exhibit a higher voltage on the anode terminal than the cathode terminal. Therefore, a bypass current is provided through the bypass circuit, thereby allowing the solar power system to continue operating without the power contribution of the respective solar panel power system.

The bypass circuit described herein includes a voltage clamp that is configured to clamp an excessive voltage across the bypass circuit in the first mode corresponding to a normal operating condition of the solar panel power system. As an example, the voltage clamp can be configured as a transistor device that is arranged between the anode terminal and the cathode terminal. For example, the transistor device can be configured as a depletion-mode field effect transistor (FET) having a gate coupled to the anode terminal and a drain coupled to the cathode terminal. Therefore, in response to the cathode terminal voltage increasing greater than a threshold voltage relative to the anode terminal, the transistor device can activate to conduct a clamping current from the cathode terminal, thereby clamping the voltage across the bypass circuit to a much smaller amplitude to mitigate damage to the bypass circuit. As a result, the bypass circuit described herein can mitigate spurious voltage increases and/or can allow for a larger photovoltaic voltage being generated from a given one of the solar panel power systems (e.g., based on having larger or a greater quantity of solar panels).

As described herein, the term “activate” with respect to a transistor device corresponds to providing sufficient bias to the input terminal of the transistor device for the transistor device to act as a closed switch, thereby providing current or signal flow through the transistor device. Similarly, the term “deactivate” with respect to a transistor device corresponds to removing bias from the input terminal of the transistor device for the transistor device to act as an open switch, thereby ceasing current or signal flow through the transistor device.

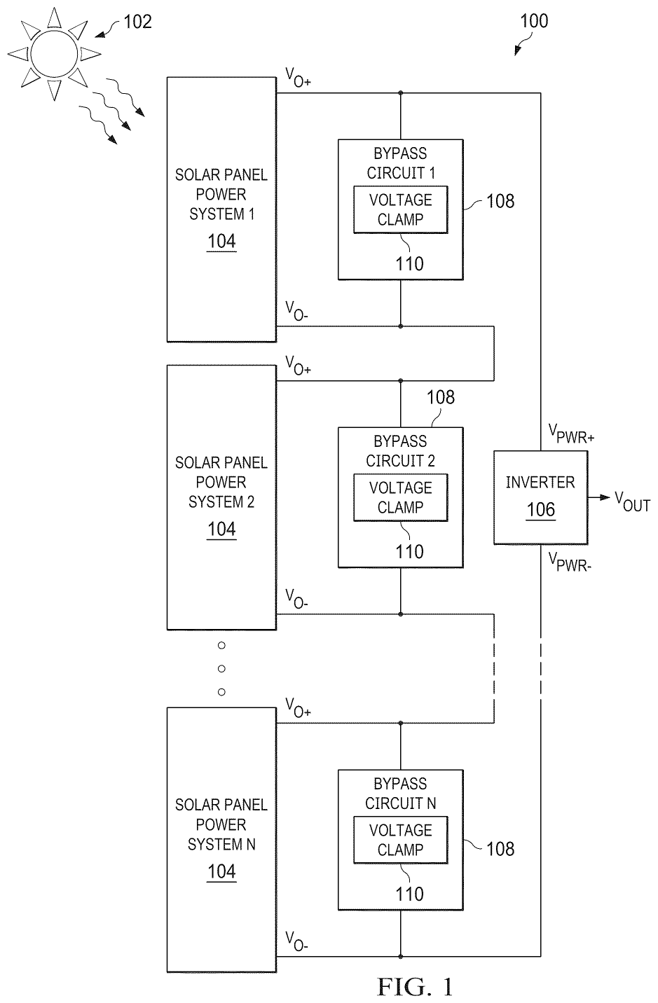

FIG. 1 is an example block diagram of a solar power system 100. The solar power system 100 can be implemented as or as part of a solar field to generate solar energy from the Sun, demonstrated at 102. The solar power system 100 includes a plurality N of solar panel power systems 104, where N is greater than one. The solar panel power systems 104 each include at least one solar panel and associated electronic circuits to provide a voltage, demonstrated as a voltage V_{O+} relative to a voltage V_{O-}, that is a portion of a total voltage, demonstrated as a voltage V_{PWR+} relative to a voltage V_{PWR-}, of the solar power system 100. Each of the solar panel power systems 104 can be arranged in series with each other and can be electrically coupled to an inverter 106, such that the V_{O-} of a given one of the solar panel power systems 104 corresponds to the V_{O+} of another one of the solar panel power systems 104. The inverter 106 is therefore configured to provide an output voltage V_{OUT} that is a rectified version of the voltages V_{O+} generated by each of the solar panel power systems 104, and thus the voltage V_{PWR+}.

In the example of FIG. 1, the solar power system 100 includes a bypass circuit 108 arranged in parallel with each of the solar panel power systems 104. The bypass circuits 108 provide an alternate current path for the current associated with the voltage V_{PWR+} in response to a deactivation of or a failure condition of the respective solar panel power system 104. In the example of FIG. 1, each of the bypass circuits 108 includes a voltage clamp 110. The voltage clamp 110 is configured to clamp a difference amplitude between the voltage V_{O+} and the voltage V_{O-} across the respective one of the bypass circuits 108 to a predefined amplitude. Therefore, the voltage clamp 110 can be configured to mitigate damage to the respective bypass circuit 108 in response to an overvoltage condition across the respective bypass circuit 108.

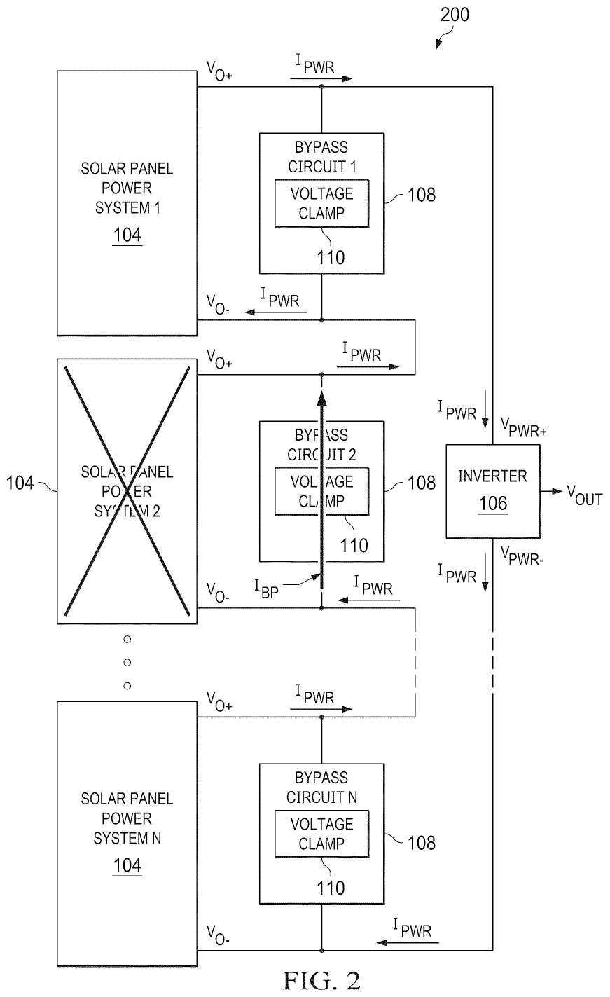

FIG. 2 is an example diagram 200 of the solar power system 100 of the example of FIG. 1. The solar power system 100 is the same as demonstrated in the example of FIG. 1, and thus like reference numbers are used in the example of FIG. 2.

As an example, each of the bypass circuits 108 can include an ideal diode controller and a bypass switch. For example, the ideal diode controller can include an anode terminal that is provided the voltage V_{O-} and a cathode terminal that is provided the voltage V_{O+}. The ideal diode controller can also include a control terminal that is configured to control the bypass switch that is configured to conduct a bypass current. In the example of FIG. 2, a power current I_{PWR} is demonstrated as having a current path that is provided through the series-connected solar panel power systems 104 and the inverter 106.

For example, during a first mode corresponding to a normal operating condition of the respective solar panel power system 104, the respective bypass circuit 108 can exhibit a higher voltage on the cathode terminal than the anode terminal. Thus, the voltage V_{O+} has an amplitude that is greater than the amplitude of the voltage V_{O-} across the bypass circuit 108. Therefore, no current is provided through the bypass circuit 108. Instead, the respective solar panel power system 104 provides a portion of the current I_{PWR} through the inverter 106.

However, the example of FIG. 2 demonstrates a deactivated condition or failure condition of a second one of the solar panel power systems 104 (“SOLAR PANEL POWER SYSTEM 2”). The deactivated or failure condition can correspond to a second mode of the respective solar panel power system 104. In the second mode of the respective solar panel power system 104, the bypass circuit 108 can exhibit a higher voltage on the anode terminal than the cathode terminal. Therefore, the voltage V_{O-} has an amplitude that is greater than the amplitude of the voltage V_{O+} across the bypass circuit 108, resulting in a reverse voltage across the solar panel power system 104. In response to the second mode, the bypass circuit 108 conducts a bypass current I_{BP} through the bypass circuit 108. The bypass current I_{BP} can correspond to the current I_{PWR} passing through the bypass circuit 108 instead of the deactivated or failed solar panel power system 104. As a result, the remaining solar panel power systems 104 can continue to provide the current I_{PWR} in the current loop through the inverter 106. Accordingly, the solar power system can continue operating without the power contribution of the respective deactivated or failed solar panel power system 104.

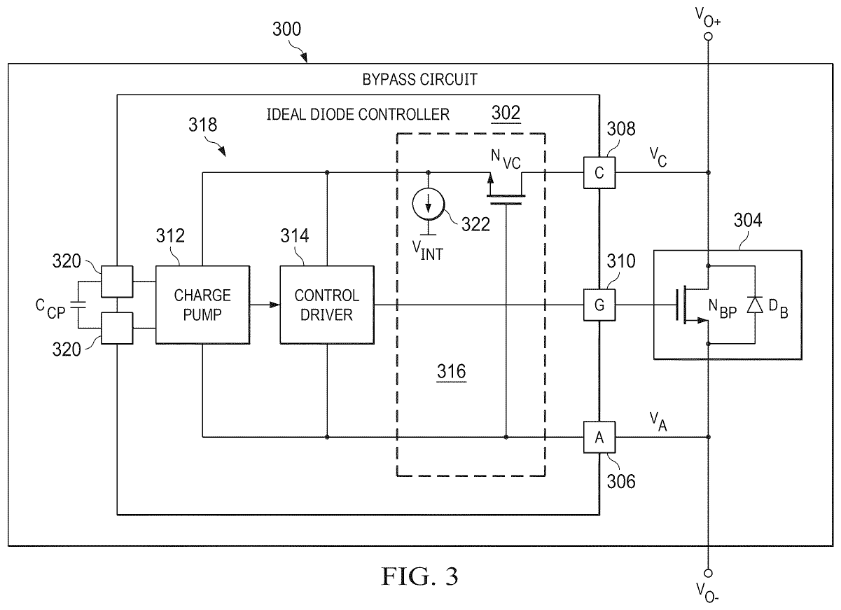

FIG. 3 is an example of a bypass circuit 300. The bypass circuit 300 can correspond to one of the bypass circuits 108 in the example of FIGS. 1 and 2. Therefore, reference is to be made to the examples of FIGS. 1 and 2 in the following description of the example of FIG. 3.

The bypass circuit 300 includes an ideal diode controller 302 and a bypass switch 304. In the example of FIG. 3, the bypass switch 304 is demonstrated as a transistor device N_{BP} that includes a body-diode D_{B}. As an example, the ideal diode controller 302 can be arranged as or as part of an integrated circuit (IC). The ideal diode controller 302 includes an anode terminal (“A”) 306, a cathode terminal (“C”) 308, and a control terminal (“G”) 310 that is coupled to a control terminal (e.g., gate) of the bypass switch 304. The cathode terminal 308 is arranged to receive the voltage V_{O-} of the respective one of the solar panel power systems 104, such that a cathode voltage V_{C} can be approximately equal to the voltage V_{O-}. The anode terminal 306 is arranged to receive the voltage V_{O+} of the respective one of the solar panel power systems 104, such that an anode voltage V_{A} can be approximately equal to the voltage V_{O+}. As an example, the bypass circuit 300 can be coupled to the outputs of the respective solar panel power system 104, and thus to the voltages V_{O+} and/or V_{O-}, by additional circuit components, such as capacitor(s) (not shown).

The ideal diode controller 302 and the bypass switch 304, and thus the bypass circuit 300, are therefore configured to operate as a diode with respect to the voltages V_{O+} and V_{O-}. For example, as described in greater detail herein, no current is provided through the bypass switch 304 in response to the amplitude of the cathode voltage V_{C} being greater than the amplitude of the anode voltage V_{A}. However, in response to the amplitude of the anode voltage V_{A} being greater than the amplitude of the cathode voltage V_{C}, the bypass circuit 300 conducts the bypass current I_{BP} through the bypass switch 304. Therefore, the bypass current I_{BP} can allow the solar power system 100 to continue to operate to generate the current I_{PWR}, such as demonstrated in the diagram 200 in the example of FIG. 2.

In the example of FIG. 3, the ideal diode controller 302 also includes charge pump 312, a control driver 314, and a voltage clamp 316. Each of the charge pump 312 and the control driver 314 are arranged between a terminal 318 and the anode terminal 306. The control driver 314 is demonstrated as being coupled to the control terminal 310, and thus coupled to the control terminal (e.g., gate) of the transistor device N_{BP} of the bypass switch 304. The control driver 314 is thus configured to control operation of the transistor device N_{BP} of the bypass switch 304, as well as other circuit functions of the ideal diode controller 302. The charge pump 312 is configured to build a voltage across a capacitor C_{CP} to provide sufficient power for the control driver 314 to activate the transistor device N_{BP} of the bypass switch 304 during a second mode, as described in greater detail herein. In the example of FIG. 3, the capacitor C_{CP} is demonstrated as arranged between a set of terminals 320 that can correspond to external terminals of the ideal diode controller 302.

The voltage clamp 316 includes a transistor device N_{VC} having a control terminal (e.g., gate) coupled to the anode terminal 306, an input terminal (e.g., drain) coupled to the cathode terminal 308, and an output terminal (e.g., source) coupled to the terminal 318. As an example, the transistor device N_{VC} can be configured as a depletion-mode transistor device. The voltage clamp 316 is demonstrated as including a current source 322 that is coupled to an internal reference voltage V_{INT} of the ideal diode controller 302. The current source 322 and internal reference voltage V_{INT} are demonstrated diagrammatically to illustrate that the transistor device N_{VC} is configured to activate and conduct a clamping current, as described in greater detail herein. As an example, the output terminal of the transistor device N_{VC} can be coupled to the anode to provide the internal reference voltage V_{INT}.

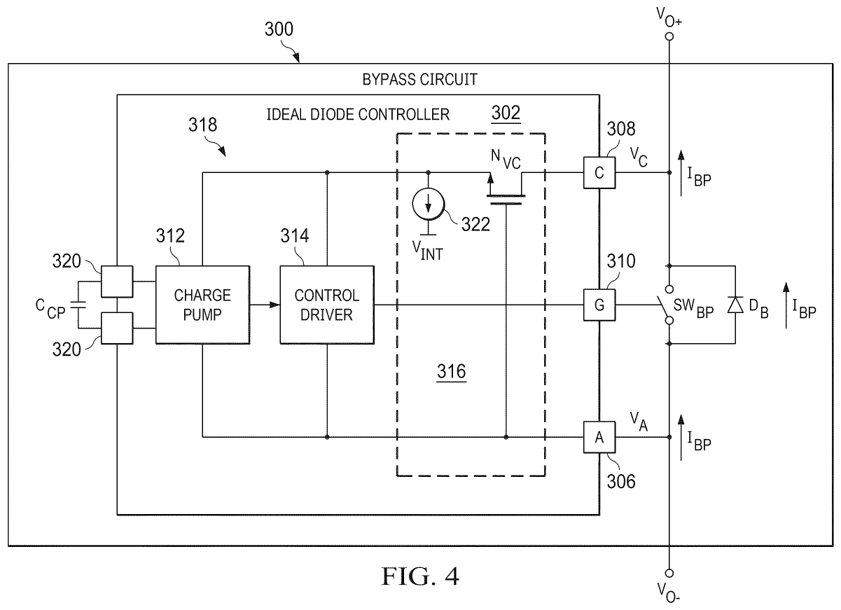

As described above, the bypass circuit 300 can operate as a diode with respect to the voltages V_{O+} and V_{O-} to provide a current path in only one direction, from the anode terminal 306 to the cathode terminal 308, during a second mode of the respective solar panel power system 104 to which the bypass circuit 300 is coupled. Additionally, the voltage clamp 316 is configured to clamp an amplitude of the difference between the cathode voltage V_{C} and the anode voltage V_{A} to a predefined amplitude, such as a threshold voltage of the transistor device N_{VC}, in a first mode of the respective solar panel power system 104. The operation of the bypass circuit 300 in the first and second modes of the respective solar panel power system 104 is demonstrated in greater detail in the examples of FIGS. 4-6.

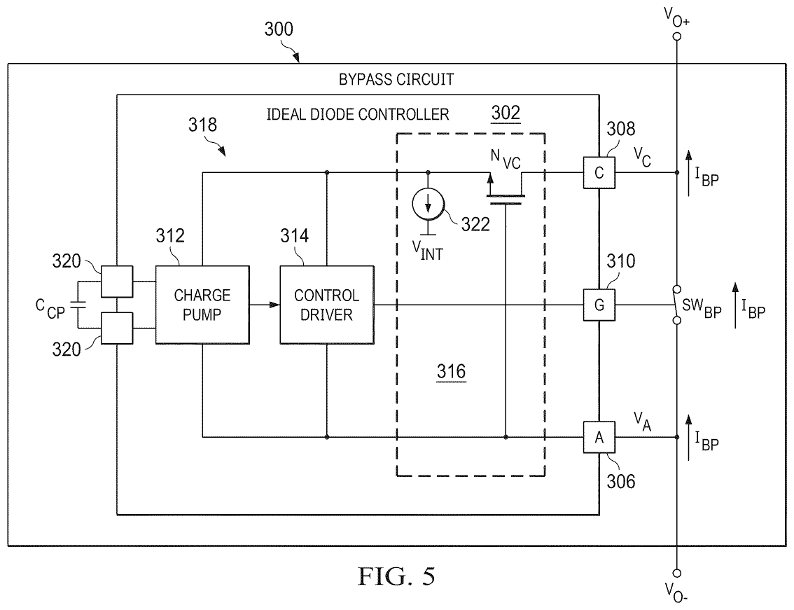

FIG. 4 is an example diagram 400 of operation of the bypass circuit 300 of the example of FIG. 3. FIG. 5 is another example diagram 500 of operation of the bypass circuit 300 of the example of FIG. 3. The diagrams 400 and 500 demonstrate operation of the bypass circuit 300 in the second mode of the respective solar panel power system 104, and thus during a deactivated condition or failure condition of the respective solar panel power system 104. Therefore, reference is to be made to the examples of FIGS. 1-3 in the following description of the examples of FIGS. 4 and 5.

The diagram 400 in the example of FIG. 4 demonstrates an initial state of the bypass circuit 300 in the second mode of the respective solar panel power system 104. In the example of FIG. 4, the amplitude of the anode voltage V_{A} is greater than the amplitude of the cathode voltage V_{C}. Therefore, the bypass current I_{BP} is conducted from the voltage V_{O-} to the voltage V_{O+} in a reverse voltage condition with respect to the associated solar panel power system 204, and is thus conducted in a forward bias of the ideal diode controller 302 from the anode terminal 306 to the cathode terminal 308. In the example of FIG. 4, the transistor device N_{BP} of the bypass switch 304 is demonstrated as a switch SW_{BP} in an open state, and thus non-conducting of the bypass current I_{BP}. Instead, the bypass current I_{BP} is initially conducted through the body diode D_{B} (e.g., from the anode to the cathode of the body diode D_{B}).

In response to the bypass current I_{BP}, the voltage difference between the anode voltage V_{A} and the cathode voltage V_{C} provides a voltage across the charge pump 312. As described above, the transistor device N_{VC} can be configured as a depletion-mode FET, such that the transistor device N_{VC} can be activated in the second mode (e.g., based on the amplitude of the anode voltage V_{A} providing a sufficient gate-source bias) to provide the cathode voltage V_{C} (e.g., or a voltage approximately equal in amplitude to the cathode voltage V_{C}) to the terminal 318, and thus to the charge pump 312. The charge pump 312 can thus provide charge across the capacitor C_{CP}, which can be implemented as a power source to the control driver 314.

The diagram 500 in the example of FIG. 5 demonstrates a state of the bypass circuit 300 subsequent to the initial state in the diagram 400 in the second mode of the respective solar panel power system 104. In the example of FIG. 5, the control driver 314 receives sufficient power from the charge pump 312 to activate the transistor device N_{BP}, which is represented in the example of FIG. 5 as the switch SW_{BP} in a closed state. Therefore, the bypass current I_{BP} is conducted through the activated transistor device N_{BP} represented by the closed switch SW_{BP}. Accordingly, the bypass current I_{BP} can flow through the bypass circuit 300 to provide for sustained operation of the remaining series-connected solar panel power systems 104 after deactivation or failure of the respective solar panel power system 104 to which the bypass circuit 300 is coupled. In the example of FIG. 5, the body diode D_{B} is omitted merely for clarity, but can also conduct a portion of the bypass current I_{BP}.

The diagrams 400 and 500 in the respective examples of FIGS. 4 and 5 demonstrate independent control of the bypass circuit 300 to exhibit bypass behavior. Particularly, the control of the bypass switch 304 is independently provided internally with respect to the ideal diode controller 302, as opposed to conventional bypass circuits in which external solar control circuitry, such as a part of the solar panel power system, provides control signals to the conventional bypass circuit, such as an activation signal to a bypass switch of the conventional bypass circuit. Accordingly, the bypass circuit 300 can still operate despite potential failure of control circuitry in the respective solar panel power system 104, thereby mitigating a potential for serious damage to the bypass circuit 300, and therefore the solar power system 100.

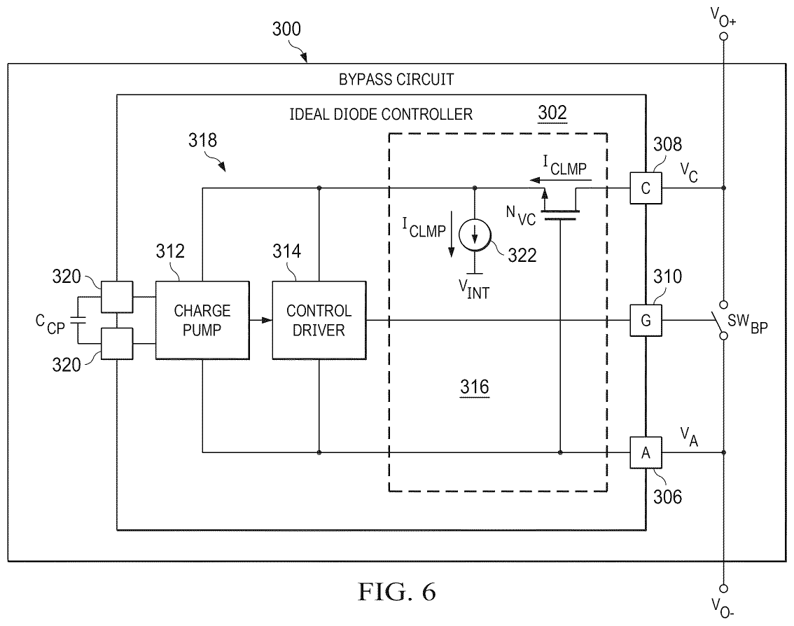

FIG. 6 is another example diagram 600 of the bypass circuit of FIG. 3. The diagram 600 demonstrates operation of the bypass circuit 300 in the first mode of the respective solar panel power system 104, and thus during a normal operating condition of the respective solar panel power system 104 during which the solar panel power system 104 generates solar power to contribute to the current I_{PWR}. Therefore, reference is to be made to the examples of FIGS. 1-3 in the following description of the examples of FIG. 6.

In the example of FIG. 6, the amplitude of the cathode voltage V_{C} is greater than the amplitude of the anode voltage V_{A}. Therefore, because the voltage V_{O+} is greater than the voltage V_{O-} in a forward voltage condition with respect to the associated solar panel power system 204, no current is provided through the bypass circuit 300. Instead, the diode operation of the bypass circuit 300 is in reverse-bias to prohibit current flow from the cathode (e.g., the cathode terminal 308) to the anode (e.g., the anode terminal 306). In the example of FIG. 6, the transistor device N_{BP} of the bypass switch 304 is demonstrated as the switch SW_{BP} in the open state, and thus non-conducting of current. In the example of FIG. 6, the body diode D_{B} is omitted merely for clarity, but likewise operates in reverse-bias to prohibit conduction of current therethrough.

As an example, the amplitude difference between the voltage V_{O+} and the voltage V_{O-} can be significant, such as resulting from a spurious voltage spike or even from normal operation of the respective solar panel power system 104 (e.g., as designed with greater photovoltaic power generation). The voltage clamp 316 is thus configured to clamp the amplitude difference between the voltage V_{O+} and the voltage V_{O-} to a predefined threshold, thereby mitigating damage of a significantly high reverse-bias of the diode operation of the bypass circuit 300.

In the example of FIG. 6, the transistor device N_{VC} is demonstrated as activated. For example, for the transistor device N_{VC} arranged as a depletion-mode FET, the transistor device N_{VC} can be activated to operate as a source-follower to conduct a clamping current I_{CLMP} from the cathode terminal 308 to the internal voltage source V_{INT}, thereby clamping the amplitude of the cathode voltage V_{C} relative to the amplitude of the anode voltage V_{A}. The activation of the transistor device N_{VC} to conduct the clamping current I_{CLMP} thus sets the amplitude of the cathode voltage V_{C} to be approximately equal to a sum of the amplitudes of the anode voltage V_{A} and a threshold voltage V_{T} of the transistor device N_{VC} (e.g., less than approximately 5V). The voltage clamp 316 therefore clamps an amplitude difference between the cathode voltage V_{C} and the anode voltage V_{A} to be approximately equal to the threshold voltage V_{T} of the transistor device N_{VC}. The source-follower arrangement of the transistor device N_{VC} can maintain the clamping of the cathode voltage V_{C} to track changes in the amplitude of the anode voltage V_{A} by the amplitude difference V_{T}.

Accordingly, the voltage clamp 316 can mitigate damage to the bypass circuit 300 from excessive voltage amplitude differences between the voltages V_{O+} and V_{O-}. As a result, the voltage clamp 316 can protect the bypass circuit 300 from spurious voltage spikes between the voltages V_{O+} and V_{O-}. As another example, the voltage clamp 316 can facilitate a design of the respective solar panel power system 104 to accommodate more photovoltaic panels to generate a greater amplitude difference between the voltages V_{O+} and V_{O-}. As a result, the voltage clamp 316 of each of the bypass circuits 300 can allow for a more effective/efficient solar power system 100.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

In this description, the term “couple” can cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

In this description, a device that is “configured to” perform a task or function can be configured (e.g., programmed and/or hardwired) at a time of manufacturing by a manufacturer to perform the function and/or can be configurable (or reconfigurable) by a user after manufacturing to perform the function and/or other additional or alternative functions. The configuring can be through firmware and/or software programming of the device, through a construction and/or layout of hardware components and interconnections of the device, or a combination thereof. Furthermore, a circuit or device that is described herein as including certain components can instead be configured to couple to those components to form the described circuitry or device. For example, a structure described herein as including one or more semiconductor elements (such as transistor devices), one or more passive elements (such as resistors, capacitors, and/or inductors), and/or one or more sources (such as voltage and/or current sources) can instead include only the semiconductor elements within a single physical device (e.g., a semiconductor die and/or integrated circuit (IC) package) and can be configured to couple to at least some of the passive elements and/or the sources to form the described structure, either at a time of manufacture or after a time of manufacture, such as by an end-user and/or a third-party.

The phrase “based on” means “based at least in part on”. Therefore, if X is based on Y, X can be a function of Y and any number of other factors.

Modifications are possible in the described embodiments, and other embodiments are possible, within the scope of the claims.

What is claimed is:

1. A circuit comprising:
an ideal diode controller comprising a voltage clamp circuit, an anode terminal, a cathode terminal, and a control terminal arranged between the anode terminal and the cathode terminal; and
a bypass switch controlled by a switch signal provided from the control terminal, the bypass switch being configured to operate in a closed state in a first mode in which a first voltage at the anode terminal is greater than or approximately equal to a second voltage at the cathode terminal to conduct a bypass current, and to operate in an open state in a second mode in which the first voltage is less than the second voltage, the voltage clamp circuit being configured to clamp an amplitude of the second voltage to a predefined threshold amplitude relative to an amplitude of the first voltage in the second mode.

2. The circuit of claim 1, wherein the voltage clamp circuit comprises a transistor device having a control terminal coupled to the anode terminal and an input terminal coupled to the cathode terminal to conduct a clamping current in response to the second voltage being greater than the first voltage.

3. The circuit of claim 2, wherein the transistor device is configured as a depletion-mode field effect transistor (FET).

4. The circuit of claim 2, wherein the transistor device also has an output terminal that is coupled to an internal voltage to act as a current source to conduct the clamping current from the cathode terminal.

5. The circuit of claim 2, wherein the ideal diode controller circuit further comprises:
a charge pump arranged between an output terminal of the transistor device and the anode terminal, the charge pump being configured to store energy in response to the bypass current in the first mode; and
a control driver arranged between the output terminal of the transistor device and the anode terminal, the control driver being configured to provide the switch signal based on stored energy in the charge pump to set the bypass switch in the closed state in the first mode.

6. The circuit of claim 2, wherein the predefined threshold amplitude corresponds to a threshold voltage of the transistor device.

7. The circuit of claim 1, wherein the ideal diode controller circuit further comprises:
a charge pump that is configured to store energy in response to the bypass current in the first mode; and
a control driver configured to provide the switch signal based on the stored energy in the charge pump to set the bypass switch in the closed state in the first mode.

8. The circuit of claim 7, wherein the bypass switch comprises a diode configured to initially conduct the bypass current to store the energy in the charge pump, such that the control driver is configured to provide the switch signal to set the bypass switch in the closed state to continue to conduct the bypass current.

9. The circuit of claim 8, wherein the bypass switch is configured as a metal oxide semiconductor field effect transistor (MOSFET), and wherein the diode is a body diode of the MOSFET.

10. A solar power system comprising the circuit of claim 1, wherein the circuit is arranged in parallel with one of a plurality of series-connected solar panel power systems.

11. A solar power system comprising:
a plurality of solar panel power systems arranged in series;
an inverter electrically coupled to the solar panel power systems; and
a plurality of bypass circuits that are each arranged in parallel with a respective one of the solar panel power systems, each of the bypass circuits being configured to conduct a bypass current via a bypass switch in a first mode of the bypass circuits corresponding to a first condition of the respective one of the solar panel power systems, and to clamp a voltage across the respective one of the bypass circuits to a predefined threshold amplitude in a second mode of a respective one of the solar panel power systems corresponding to a second condition of the respective one of the solar panel power systems.

12. The solar power system of claim 11, wherein each of the bypass circuits comprises:
the bypass switch; and
an ideal diode controller comprising an anode terminal, a cathode terminal, a control terminal arranged between the anode terminal and the cathode terminal, and a voltage clamp circuit, the voltage clamp circuit being configured to clamp the voltage across the respective one of the bypass circuits to the predefined threshold amplitude in the second mode of the respective one of the bypass circuits.

13. The solar power system of claim 12, wherein the voltage clamp circuit comprises a transistor device having a control terminal coupled to the anode terminal and an input terminal coupled to the cathode terminal to conduct a clamping current in the second mode.

14. The solar power system of claim 13, wherein the transistor device is configured as a depletion-mode field effect transistor (FET), wherein the predefined threshold amplitude corresponds to a threshold voltage of the depletion-mode FET.

15. The solar power system of claim 13, wherein the transistor device also has an output terminal that is coupled to a reference voltage to act as a current source to conduct the clamping current from the cathode terminal.

16. A circuit comprising:
a charge pump having a first input, a second input, and an output;
a control driver having a first input, a second input, and an output, the first input of the control driver being coupled to the first input of the charge pump, the second input of the control driver being coupled to the second input of the charge pump;
a voltage clamp circuit having a control input, a first terminal, and a second terminal, the control input being coupled to the second inputs of each of the charge pump and the control driver, the first terminal being coupled to the first input of each of the charge pump and the control driver;
a first bypass terminal coupled to the second input of each of the charge pump and the control driver;
a second bypass terminal coupled to the second terminal of the voltage clamp circuit; and
a control bypass terminal coupled to the output of the control driver.

17. The circuit of claim 16, wherein the voltage clamp circuit comprises a transistor device having the control input, an input terminal, and an output terminal, wherein the control input of the transistor device is coupled to the first bypass terminal, the input terminal of the transistor device is coupled to the second bypass terminal, and the output terminal of the transistor device is coupled to the first input of each of the charge pump and the control driver.

18. The circuit of claim 17, wherein the output terminal of the transistor device is adapted to be coupled to a reference voltage.

19. The circuit of claim 17, wherein the transistor device is configured as a depletion-mode field effect transistor (FET).

20. The circuit of claim 16, wherein the voltage clamp circuit is adapted to be coupled to a reference voltage at the first terminal.
